(19) United States
(12) Patent Application Publication
(10) Pub. No.: US 2009/0273376 A1
(43) Pub. Date: Nov. 5, 2009

(54) AC/DC CONVERTERS AND METHODS OF MANUFACTURING SAME

(75) Inventors: Siarhei KALODKA, Taipei (TW); Sergey Gaitukevich, Taipei (TW); Vitali Maziarkin, Taipei (TW); Alan Wang, Taipei (TW); Chen-Hui Tsay, Taipei (TW)

Correspondence Address: Eastwind Consultants Company Limited, 7F, No. 1, Alley 30, Lane 358,, Rueiguang Road, Neihu District, Taipei, 114, TW

(73) Assignee: Shamrock Micro Devices

(21) Appl. No.: 12/389,357

(22) Filed: Feb. 19, 2009

Related U.S. Application Data
(60) Provisional application No. 61/029,924, filed on Feb. 20, 2008.

(51) Int. Cl. H03L 7/00; H01L 21/26; H01L 21/336; H01L 29/78

(52) U.S. Cl. 327/143; 438/514; 438/286; 257/337; 257/E21.328; 257/E21.417; 257/E29.256

(57) ABSTRACT

The present invention discloses AC/DC converters and methods of manufacturing the same. The method includes providing a substrate; forming an oxide layer on a top surface of the substrate; applying a photo-resist layer on the oxide layer to define a well region; performing an ion-implantation in the well region using a dopant; and driving in atoms of the dopant to a depth in the well region through a thermal treatment, wherein the driving in process provides a concentration profile of the dopant in the well region such that the semiconductor structure has a high breakdown voltage.

### CROSS-REFERENCE TO RELATED APPLICATIONS

This application is related to and claims priority to U.S. provisional patent application, U.S. Provisional Application No. 61/029,924, filed on Feb. 20, 2008, by the applicants Siarhei Kalodka, Sergey Gaitukevich, Vitali Maziarkin, Alan Wang, and Chen-Hui Tsay, entitled “AC/DC converters and methods of manufacturing same.”

### FIELD OF THE INVENTION

The present invention relates to AC/DC converters and the processes for making the same.

### BACKGROUND OF THE INVENTION

A conventional high voltage AC/DC converter using BIPOLAR CMOS DMOS (BCD) technology typically requires at least 18˜20 lithographic masks to manufacture and generally must withstand voltage higher than 450 V. As known in the art, more lithographic masks and associating processes significantly increase production costs of a chip. Using more lithographical processes also mean that the structure tends to be more complicated and therefore more error-prone. Therefore, what is needed in the art is a novel method of manufacturing high voltage AC/DC converter using as few lithographic masks as possible.

Furthermore, in a conventional design of the integrated AC/DC converter, low-voltage PWM-controller and external components such as start-up circuitries and output MOSFET, etc are typically included. Some other conventional designs of the AC/DC converters may include integrating a high-voltage input MOSFET component into the same chip with the PWM-controller. However, the size of the conventional integrated AC/DC converter is still relatively large. Integrating these many different components in a single chip will require complicated process and results in a manufacturing cost increase. Therefore, what is needed in the art is an integrated AC/DC converter with more efficient components and simplified circuits so as to reduce the product size and lower manufacturing costs.

Additionally, when starting up a conventional AC/DC converter device, an overcharge voltage is generally undesirable. FIG. 16 shows a block diagram of a conventional AC/DC converter employing a soft-start block, such as block 320, to reduce the rising rate of the output voltage so as to prevent damage that may result from the rapid rising of the output voltage. The conventional scheme for a soft-start is to charge external capacitor Css by an internal current source, such as block 303 in FIG. 16, and sense the voltage on this capacitor to limit duty cycle until the output voltage reaches a specified value. In addition to the soft start scheme, an AC/DC converter typically comprises a phase compensation block (not shown) for synchronizing the phase of AC current. Therefore, what is needed in the art is a simplified scheme integrating the external capacitor with the small current source so that the internal capacitor can be used for both soft start and phase compensation purposes.

### SUMMARY OF THE INVENTION

It is an object of the present invention to provide a method of manufacturing a semiconductor structure. The method includes providing a substrate; forming an oxide layer on a top surface of the substrate; applying a photo-resist layer on the oxide layer to define a well region; performing an ion-implantation in the well region using a dopant; and driving in atoms of the dopant to a depth in the well region through a thermal treatment, wherein the driving in process provides a concentration profile of the dopant in the well region such that the semiconductor structure has a high breakdown voltage.

It is another object of the present invention to provide a method of manufacturing a semiconductor structure. The method includes providing a substrate having a first section and a second section; forming a first oxide layer on a top surface of the substrate; applying a first photo-resist layer on the first oxide layer to define a first well region; performing a first ion-implantation in the first well region using a first dopant; driving in atoms of the first dopant to a first depth in the first well region through a thermal treatment; stripping the first oxide layer, forming a second oxide layer on the top surface of the substrate; applying a second photo-resist layer on the second oxide layer to define a second well region; performing a second ion-implantation in the second well region using a second dopant; driving in atoms of the second dopant to a second depth in said second well region through the thermal treatment, wherein the thermal treatment is at least 6,000 degree-C.·hour, the first depth is greater than 5.5 micron, and the second depth is greater than 3 micron.

It is yet another object of the present invention to provide an integrated circuit manufactured in the steps of the method as above. The integrated circuit includes: a single start-up and supply voltage controller for integrating a start-up source and a supply voltage; a first transistor electrically connected to the single start-up and supply voltage controller for converting high input voltage to internal supply voltage of the single start-up and supply voltage controller, wherein the first transistor is a DMOS transistor.

Other objects of the present invention can be readily ascertained by one of ordinary skilled in the arts upon review of the detailed descriptions of the preferred embodiments.

### BRIEF DESCRIPTION OF THE DRAWINGS

FIGS. 1-11 are cross-sectional views illustrating a method of manufacturing an AC/DC converter in accordance with one preferred embodiment of the present invention;

FIG. 12 is a block diagram of one example of an AC/DC converter in accordance with one preferred embodiment of the present invention;

FIG. 13 is a block diagram of one example of an AC/DC converter in accordance with one preferred embodiment of the present invention;

FIG. 14 is a circuit diagram of one example of an AC/DC converter in accordance with one preferred embodiment of the present invention;

FIG. 15 is a block diagram of one example of an AC/DC converter in accordance with one preferred embodiment of the present invention;

FIG. 16 is a block diagram of a conventional AC/DC converter; and

FIG. 17 is a block diagram of one example of an AC/DC converter in accordance with one preferred embodiment of the present invention.

### DETAILED DESCRIPTION OF THE PREFERRED EMBODIMENTS

Reference will now be made in detail to the embodiments of the present invention. Examples of embodiments are illustrated in the accompanying drawings, wherein like reference numbers refer to like elements throughout the specification.

In one preferred embodiment of the present invention, the AC/DC converter is a high voltage AC/DC converter that may be in as few as 11 lithographic masks. According to one preferred embodiment of the present invention, high voltage NLDMOS and HVNMOS structures are manufactured. However, it is to be noted that this manufacturing process can also be used to produce other structures such as low voltage CMOS transistors, bipolar transistors and passive components.

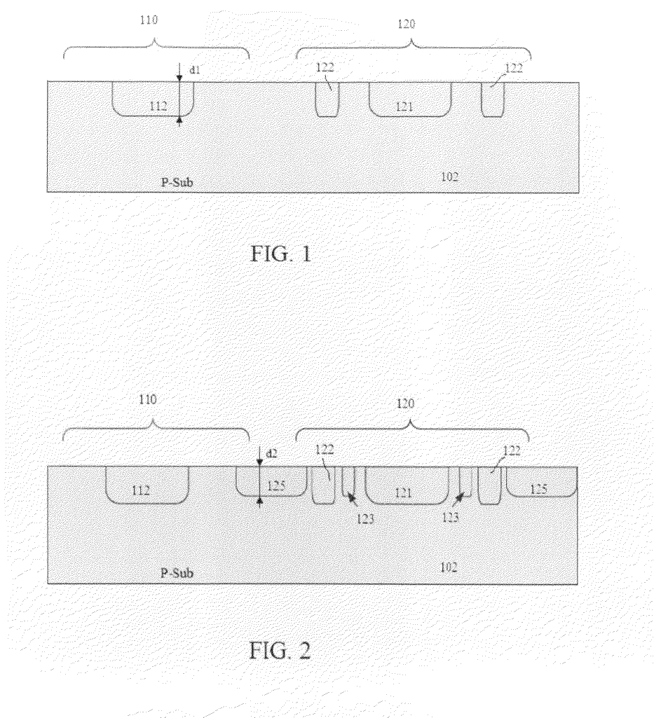

FIGS. 1-11 are cross-sectional views illustrating a method of manufacturing an AC/DC converter in accordance with one preferred embodiment of the present invention. Referring now to FIG. 1, an N-well is formed. As illustrated in FIG. 1, a substrate 102, preferably but not limited to a P-type substrate, may have two sections, one to be formed as an NLDMOS 110, and the other to be formed as an HVNMOS 120. In one preferred embodiment, several N-wells 112, 121, 122 may be formed in the substrate 102.

In accordance with the present invention, the formation of N-Wells may be achieved by first performing an N-well oxidation to form a thin oxide layer at the top surface of the substrate 102. Then, an application of a photo-resist layer and lithographical procedure may be followed to define the positions where the N-wells are to be formed. Next, N-well implantation may be carried out, for example, using phosphorus as a dopant with a proper concentration and energy. After the implantation, plasma chemical treatment and photo-resist stripping may then be performed respectively, and the photo-resist layer may be removed from the surface of the substrate. Subsequently, the dopant phosphorus atoms may be driven in to a preferential depth through thermal treatment under atmosphere. Given that the depth of the N-well junction will increase as the applied thermal energy increases, the total thermal energy applied during the thermal treatment may be, for example, at least 6,000 degree-C.·hour.

In one preferred embodiment of the present invention, the N-well drive-in procedure provides a concentration profile of the dopant in the N-well such that the final MOS structure may have desirable high breakdown voltage characteristics. For example, a desirable high breakdown voltage may be 700V in operation. The junction depth d1 of the N-wells 112, 121, 122 in FIG. 1 may be greater than 5.5 micron after the drive-in procedure. After the drive-in procedure, the oxide layer may then be stripped using conventional techniques in the art.

Turning now to FIG. 2, which illustrates a P-well formation. As can be seen from FIG. 2, several P-wells 123, 125 may be formed in the substrate 102. Similar to the formation of the N wells, first, a P-well oxidation may be performed to form a thin oxide layer at the top surface of the substrate 102. Then, an application of photo-resist layer and lithographical procedure may be followed to define the positions where the P-wells are to be formed. Next, P-well implantation may be carried out, for example, using boron as a dopant with a suitable concentration and energy. After the implantation, the photo-resist layer may then be removed from the surface of the substrate. Subsequently, the dopant boron atoms may be driven in to a preferential depth through thermal treatment. Given that the depth of the P-well junction will increase as the applied thermal energy increases, the total thermal energy applied during the thermal treatment may be, for example, at least 6,000 degree-C.·hour.

In one preferred embodiment of the present invention, the P-well drive-in procedure provides a concentration profile of the boron atoms in the P-well such that the final MOS structure may have desirable high breakdown voltage characteristics. For example, a desirable high breakdown voltage may be 700V in operation. The depth d2 of the P-wells 123, 125 in FIG. 2 may be greater than 3 micron and the depth d1 of the N-wells 112, 121, 122 may be greater than 5.5 micron after the drive-in procedure. After the drive-in procedure, the oxide layer may then be stripped using conventional techniques in the art.

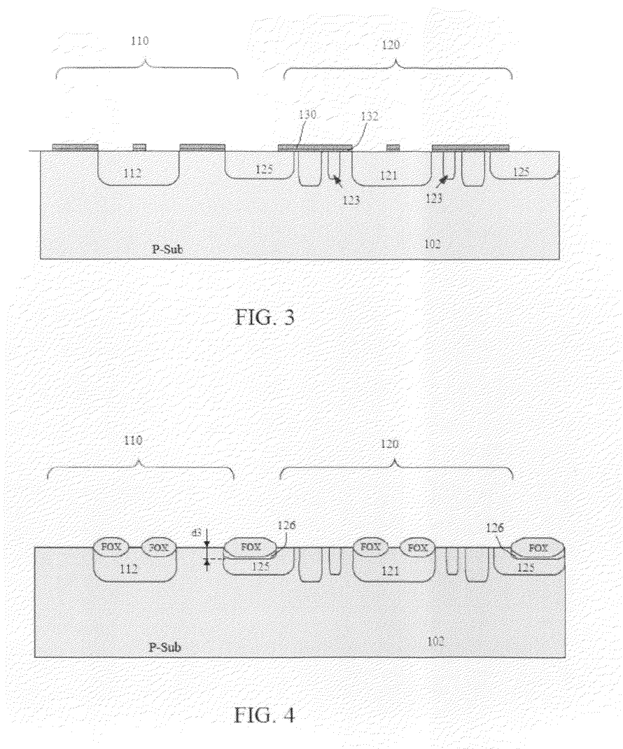

FIG. 3 illustrates a formation of an active area. First, oxidation may be carried out to form a thin oxide layer 13 Oat the top surface of the substrate. A Si₃N₄ layer 132 may then be deposited on top of the oxide layer 130. Next, a photo-resist layer (not shown) may be applied on the Si₃N₄ layer 132. Then, the active areas may be defined through lithography and exposed by etching the Si₃N₄ layer 132 that has not been covered by the photo-resist pattern. The remaining photo-resist pattern may then be stripped, leaving the structure shown in FIG. 3.

According to the present invention, P-fields within the P-well region may then be formed so as to increase the parasitic threshold voltage of the final device. To form the P-fields, a photo-resist layer with a predetermined pattern may be first formed through a conventional lithography process, in which the predetermined pattern exposes only the areas where the P-fields are to be formed. Afterwards, a P-field implantation may be carried out using, for example, boron as an implant. The photo-resist layer may then be stripped off, followed by a P-field drive-in so that the boron ions may reach a deeper depth in the substrate. As shown in FIG. 4, the depth d3 of the P-field regions 126 may be, for example, greater than 3 micron after the drive-in procedure. Field oxide structures (FOX) may then be formed in the regions not covered by the Si₃N₄ layer 132 using a conventional heat treatment. After the FOX are formed, the Si₃N₄ layer 132 may then be stripped. The resulting structure is shown in FIG. 4, in which two P-field regions 126 may be formed in P-well regions 125.

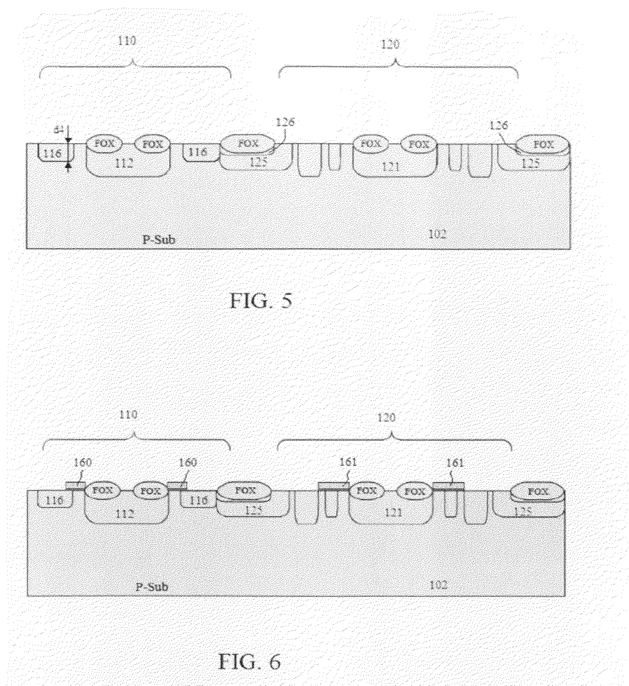

Turning now to FIG. 5. According to the present invention, a P-BASE region may be formed by the conventional photo-resist application and lithography techniques. Then, a P-BASE implantation, photo-resist stripping and driving-in the BASE implant may follow. In one preferred embodiment of the present invention, the depth d4 of the P-BASE regions 116 may be, for example, greater than 3 micron after the drive-in procedure. The resulting structure is shown in FIG. 5, in which two P-BASE regions 116 may be formed within the NLDMOS 110 at both sides of the N-well region 112.

According to the present invention, the GATE may then be formed. A layer of poly-silicon may be deposited first on the structure shown in FIG. 5 followed by an oxidation. Then, oxidation against the poly-silicon layer may be carried out. Next, a lithography process defining the GATE may be carried out following the conventional lithographical techniques. Subsequently, anisotropic plasma etching may be carried out. After stripping the photo-resist layer the resulting structure is shown in FIG. 6. As shown in FIG. 6, two GATE structures 160 are formed for the NLDMOS 110, and two GATE structures 161 are formed for the HVNMOS 120.

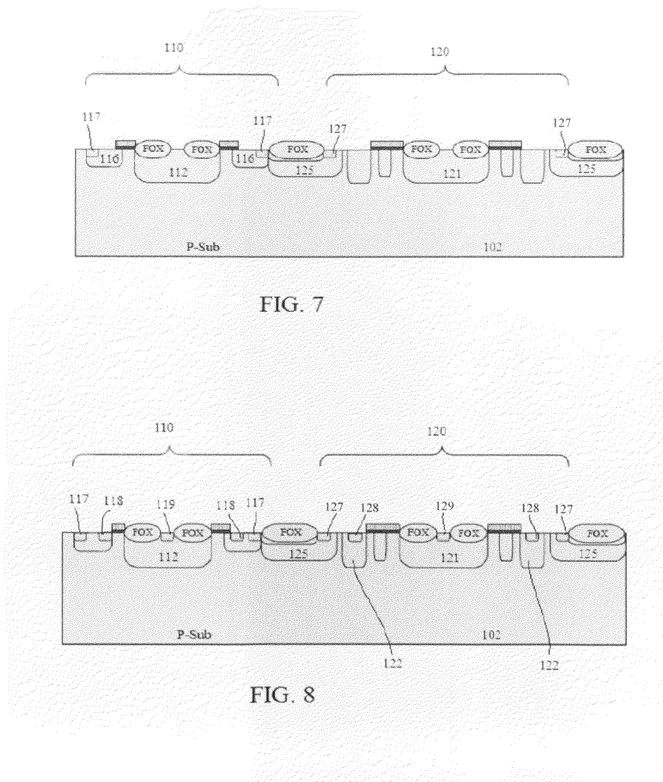

As shown in FIG. 7, P+ regions in the P-BASE of the NLDMOS 110 and the P-well of the HVNMOS 120 may then be formed. These P+ regions, along with the N+ regions to be formed later, may be where the contact metal lines will connect to the NLDMOS and HVNMOS. The formation of P+ regions may be done with the conventional lithography and implantation processes. The resulting structure is shown in FIG. 7, in which two P+ regions 117 may be formed in the P-BASE regions 116 of the NLDMOS, and two P+ regions 127 may be formed in the P-well regions 125 of the HVNMOS.

Turning now to FIG. 8, which illustrates the formation of N+ regions in the P-BASE of the NLDMOS and in N-well of both the NLDMOS and the HVNMOS. As mentioned before, these N+ regions may be formed to connect to the contact metal lines using the conventional lithography and implantation processes. In addition, because the ions used in N+ and P+ regions are bulkier, an additional drive-in process may be preferred so as to drive the ions to a desirable depth. The resulting structure is shown in FIG. 8, in which N+ regions 118 may be formed in the P-BASE 116 of the NLDMOS, whereas N+ regions 119, 128, 129 may be formed respectively in the N-well 112 of the NLDMOS 110 and N-well 121, 122 of the HVNMOS 120.

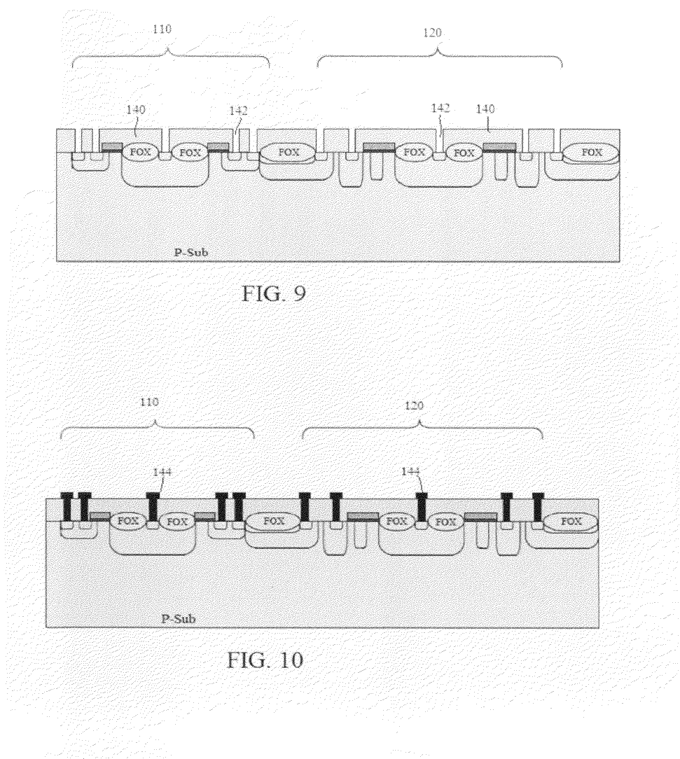

According to the present invention, contacts may then be formed in order to form the vias that may be filled with conductive materials later so as to provide electrical connection between the NLDMOS/HVNMOS and external circuitry. Referring to FIG. 9, which shows the resulting structure after the contacts have been formed. A CVD film 14O may be deposited on the structure shown in FIG. 8. Contact vias 142 may then be formed in the CVD film 140 through the lithography and etching processes. As can be seen in FIG. 9, these contact vias 142 are preferably formed at the positions corresponding to either the N+ or P+ regions that are previously formed in the P-BASE, P-well or N-well in the NLDMOS/HVNMOS.

According to the present invention, metallization in the contact vias 142 as well as on top of the CVD film 140 may be formed so that proper electrical connection may be made to these MOS devices. The material for metallization is not limited, as long as the material can sustain the conventional manufacturing process while achieving desirable electrical and physical properties.

In accordance with one embodiment, metallization may be carried out first by metal sputtering until a metal layer (not shown) may be formed on the CVD film 140. A lithography process may then be performed on the metal layer so as to define appropriate metal line patterns. As can be seen in FIGS. 9 and 10, each contact via 142 in FIG. 9 is now filled with metal 144.

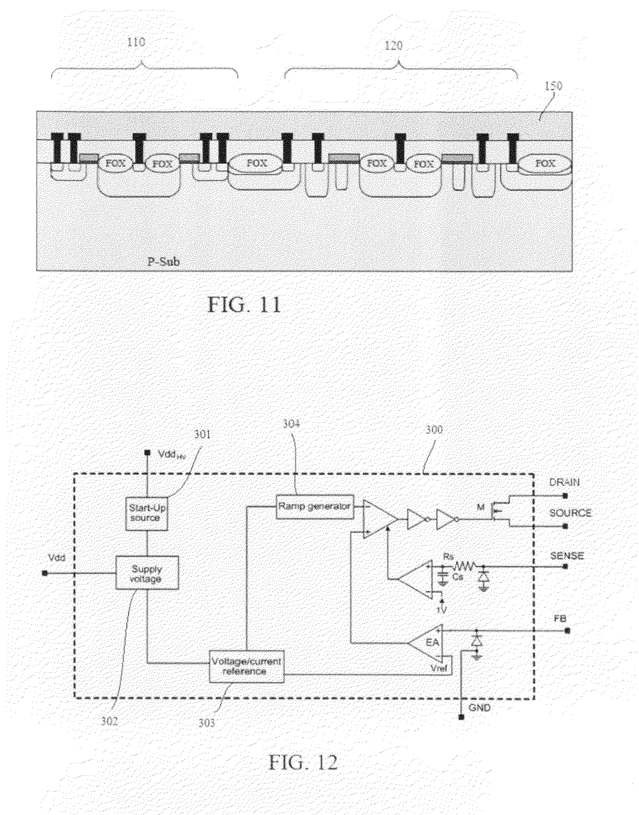

According to the present invention, one additional step may be the addition of a PAD layer. A passivated layer 150 may first be formed on the top surface of the structure shown in FIG. 10. A lithography process may then be carried out to define and open certain regions for later packaging. The resulting structure is shown in FIG. 11.

In addition to the novel NLDMOS/HVNMOS structure as well as the manufacturing process for making the same, the present application also provides a novel IC design regarding the start-up and internal voltage regulation block for an AC/DC converter. The novel AC/DC converter has a smaller PCB size, resulting in smaller product size and lower cost.

FIG. 12 shows a block diagram of an AC/DC converter in accordance with the present invention. As shown in FIG. 12, the internal design of the IC is included in dashed box 300, in which a start-up current source 301 may be connected to a supply voltage unit 302, which in turn may connect to a voltage and current reference unit 303. A ramp generator 304 may then be connected to the voltage and current reference unit 303. As mentioned above, the DMOS transistor M in this figure may serve as the output power switch. Since the chip integrates the HVNMOS (i.e. high voltage MOSFET) in the start circuitry and the NLDMOS (i.e. DMOS) as the output, the die size is relatively large.

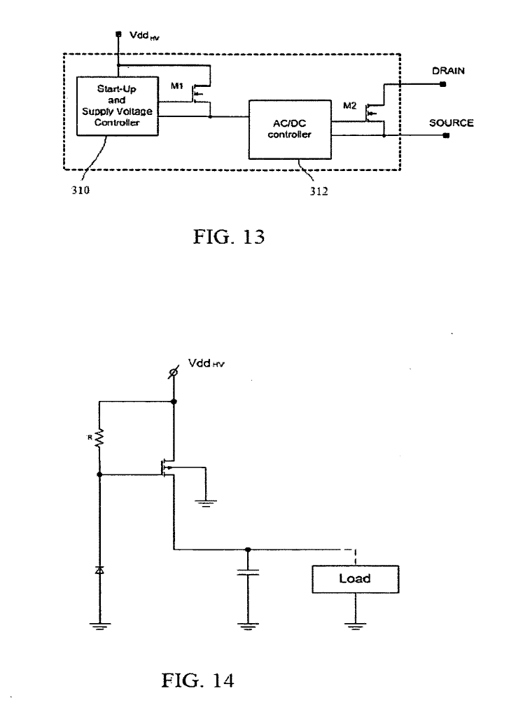

FIG. 13 shows a block diagram of one example of an AC/DC converter in accordance with one preferred embodiment of the present invention. In one embodiment of the present invention, die size of a chip may be reduced by utilizing a start-up and supply voltage controller 310 which may include the start-up source 301 and the supply voltage 302 shown in FIG. 12 and work along with a DMOS transistor M1 in FIG. 13. The other functional units such as those shown in FIG. 12 may be incorporated in a single block 312 that may work along with the DMOS transistor M2 in FIG. 13. In accordance with the present invention, transistor M1 may be used for converting high input voltage to internal supply voltage of the controller 312.

In the novel design, the input high-voltage MOSFET is replaced by a more efficient DMOS, which is the same as the output DMOS transistor M2. This is desirable since a DMOS transistor is more effective as compared to the conventional MOSFET. Because of this novel design, the overall chip size can be further reduced. As a result, not only will the cost of the chip be reduced, but the product will also be more competitive because broader applications can be achieved with smaller IC chip size. For illustration purposes, block 310 in FIG. 13 preferably includes the design as shown in FIG. 14.

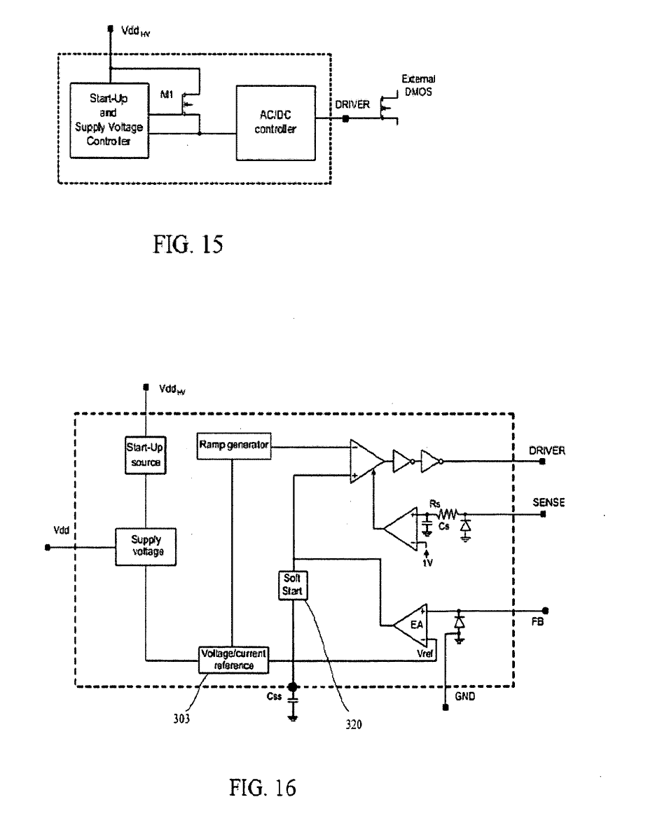

In another embodiment of the present invention, the output DMOS M2 in FIG. 13 can be placed external to the AC/DC converter IC so as to further reduce the size of the IC, as shown in FIG. 15. This embodiment may be preferred in many applications such as a large-current/high-power IC design.

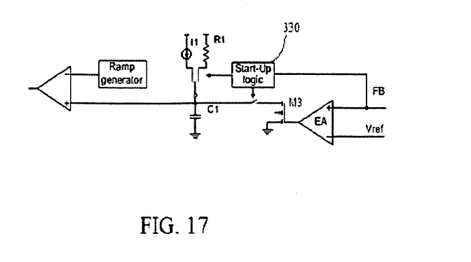

In yet another embodiment of the present invention, an AC/DC converter that enables a soft-start function is disclosed. Referring to FIG. 17, which illustrates a block diagram of one example of an AC/DC converter in accordance with one preferred embodiment of the present invention. As shown in FIG. 17, during the start-up sequence, the start-up logic block 330 may disable the error amplifier (transistor M3) and switch to current source (I1). The current source may then charge capacitor C1, and the voltage on capacitor C1 may gradually increase as a result while a duty cycle of the converter increases. When the voltage on FB pin reaches the required value, the start-up logic block 330 may then enable the error amplifier M3 and switch to load the resistor R1. Under such condition, the capacitor C1 may serve as a phase compensation unit.

The advantage of this novel IC design lies in that no external capacitor is required for the soft-start purpose, because an internal capacitor C1 is used. In other words, no extra capacitor is required. Furthermore, the internal soft-start block 330 can be switched to work with the phase compensation unit so that fewer components are required in the chip design, thereby reducing the PCB size and the cost.

Although the invention has been described in considerable detail with reference to the preferred version thereof, other versions are within the scope of the present invention. Therefore, the spirit and scope of the appended claims should not be limited to the description of the preferred version contained herein.

1. A method of manufacturing a semiconductor structure, said method comprising:
providing a substrate;
forming an oxide layer on a top surface of said substrate;
applying a photo-resist layer on said oxide layer to define a well region;
performing an ion-implantation in said well region using a dopant; and
driving in atoms of said dopant to a depth in said well region through a thermal treatment;
wherein said driving in process provides a concentration profile of said dopant in said well region such that said semiconductor structure has a high breakdown voltage.

2. The method of claim 1, wherein said thermal treatment is at least 6,000 degree-C.·hour.

3. The method of claim 1, wherein said dopant is phosphorus.

4. The method of claim 3, wherein said depth is greater than 5.5 micron.

5. The method of claim 3, wherein said well region is an N-well region.

6. The method of claim 1, wherein said depth is greater than 3 micron.

7. The method of claim 6, wherein said dopant is boron.

8. The method of claim 6, wherein said well region is a P-well region.

9. A method of manufacturing a semiconductor structure, said method comprising:
providing a substrate having a first section and a second section;
forming a first oxide layer on a top surface of said substrate;
applying a first photo-resist layer on said first oxide layer to define a first well region;
performing a first ion-implantation in said first well region using a first dopant;
driving in atoms of said first dopant to a first depth in said first well region through a thermal treatment;
stripping said first oxide layer,
forming a second oxide layer on said top surface of said substrate;
applying a second photo-resist layer on said second oxide layer to define a second well region;
performing a second ion-implantation in said second well region using a second dopant;
driving in atoms of said second dopant to a second depth in said second well region through said thermal treatment,
wherein said thermal treatment is at least 6,000 degree-C.·hour, said first depth is greater than 5.5 micron, and said second depth is greater than 3 micron.

10. The method of claim 9, further comprising:
forming a third oxide layer on said top surface of said substrate;
depositing a silicon nitride layer on top of said third oxide layer;
applying a third photo-resist layer on said silicon nitride layer to define an active area;
etching a portion of said silicon nitride layer not covered by said third photo-resist layer after a lithography process; and
stripping a remaining portion of said third photo-resist layer so as to form a non-active area.

11. The method of claim 10, further comprising:
forming a fourth photo-resist layer with a predetermined pattern;
exposing an area to form a field region;
using a third dopant as an implant to perform a field implantation;
driving in atoms of said third dopant to reach a third depth in said field region;
forming a field oxide structure in a region not covered by said silicon nitride layer;
stripping said silicon nitride layer to form said field region in said second well region.

12. The method of claim 11, further comprising:
forming a base region;
driving in said base region to reach a fourth depth within said first section of said substrate at both sides of said first well region;
forming a gate structure in said first and second sections of said substrate;
forming a first ion region in said base region of said first section and in said second well region of said second sections of said substrate;
forming a second ion region in said base region of said first section and in said first well region of said first and second sections of said substrate;
forming contact vias in a CVD film deposited on said substrate in positions corresponding to said first ion region or said second ion region; and
filling said contact vias with a metal to provide electrical connection between said first and said second sections of said substrate.

13. The method of claim 12, further comprising:
forming a passivated layer on said top surface of said substrate; and
defining additional regions on said passivated layer.

14. The method of claim 11, wherein said third depth is greater than 3 micron.

15. The method of claim 12, wherein said fourth depth is greater than 3 micron.

16. An integrated circuit manufactured in the steps of a method as claimed in claim 1, said integrated circuit comprising:
a single start-up and supply voltage controller for integrating a start-up source and a supply voltage;
a first transistor electrically connected to said single start-up and supply voltage controller for converting high input voltage to internal supply voltage of said single start-up and supply voltage controller,
wherein said first transistor is a DMOS transistor.

17. The integrated circuit of claim 16, further comprising:
an AC/DC controller electrically connected to said single start-up and supply voltage controller; and
a second transistor electrically connected to said AC/DC controller, wherein said second transistor is a DMOS transistor.

18. The integrated circuit of claim 17, wherein said second transistor is external or internal to said integrated circuit.

19. The integrated circuit of claim 17, further comprising:
a start-up logic for selectively enabling an error amplifier depending on a required value reached by an FB pin, and
an internal capacitor acting as a phase compensation unit when said start-up logic enables said error amplifier for synchronizing a phase of an AC current.

20. The method of claim 1, wherein said high breakdown voltage is 700V in operation.
